(19) United States
(12) Patent Application Publication
(10) Pub. No.: US 2005/0149791 A1
(43) Pub. Date: Jul. 7, 2005

(54) Digital signal receiving apparatus, an optical transmission apparatus therewith, and a discriminating point control method

(75) Inventor: Hiroshi Nishimoto, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/023,523

(22) Filed: Dec. 29, 2004

Related U.S. Application Data
(63) Continuation of application No. PCT/JP02/12785, filed on Dec. 5, 2002.

(51) Int. Cl. G11B 7/00; G11B 11/03; G11B 11/11; G11B 11/105; G11B 11/115; G11B 11/12; G11B 20/18; G11B 27/36; G01R 31/28

(52) U.S. Cl. 714/724

(57) ABSTRACT

A digital signal receiving apparatus is disclosed. The digital signal receiving apparatus includes a main signal discriminating unit configured to discriminate a main signal of a received signal, a monitor signal discriminating unit configured to discriminate a monitor signal of the received signal, an error monitoring unit configured to monitor a discriminating error of the monitor signal discriminating unit, and a discriminating point control unit configured to control the discriminating points of the main signal discriminating unit and the monitor signal discriminating unit. The discriminating point control unit monitors an output of the error monitoring unit, moves the discriminating point of the monitor signal discriminating unit in the amplitude directions and the phase directions such that a discriminating error occurs, detects a center of discriminating points where errors are generated, and sets the detected center of the discriminating points as the discriminating point of the main signal discriminating unit.

### CROSS-REFERENCE TO RELATED APPLICATION

This application is a U.S. continuation application filed under 35 USC 111(a) claiming benefit under 35 USC 120 and 365(c) of PCT International Application No. PCT/JP02/12785 filed on Dec. 5, 2002, which is hereby incorporated herein by reference.

### BACKGROUND OF THE INVENTION

1. Field of the Invention

The present invention generally relates to a digital signal receiving apparatus, an optical transmission apparatus therewith, and a discriminating point control method; and especially relates to a digital signal receiving apparatus that has a discriminating point control unit that controls the discriminating point of a receiving signal discriminating unit, an optical transmission apparatus therewith, and a discriminating point control method of the discriminating point control unit.

2. Description of the Related Art

In recent years and continuing, transmission speeds of optical transmission apparatuses are becoming higher and higher, optical transmission apparatuses capable of 10 Gbps are already put in practical use, and development of an optical transmission apparatus capable of 40 Gbps is furthered. As the transmission distance of the optical transmission apparatus capable of 40 Gbps is getting longer and longer with the ever-increasing transmission speed, degradation of an optical signal waveform due to polarization dispersion through an optical fiber becomes remarkable, and poses a problem in that the transmission distance is restricted.

The present invention is to mitigate the problem of the transmission distance being limited by the waveform degradation due to the polarization dispersion. Here, an example of a conventional system wherein polarization dispersion is automatically compensated for is shown in FIG. 1 (refer to Non-Patent Reference 1).

The system shown in FIG. 1 includes an optical signal transmitting unit 1, an optical fiber 2, a wavelength dispersion compensating unit 3, a polarization dispersion compensating unit 4, an optical signal receiving unit 5, a discriminating unit 6, a compensation control unit 7, and a degradation monitoring unit 8.

The optical signal transmitting unit 1 provides an optical digital signal to the optical fiber 2. The optical digital signal is subjected to wavelength dispersion and polarization dispersion while being transmitted through the optical fiber 2. Then, the wavelength dispersion and the polarization dispersion are compensated for by the wavelength dispersion compensating unit 3 and the polarization dispersion compensating unit 4 on the receiving side. The compensated optical digital signal is converted into an electrical signal by the optical signal receiving unit 5, and the amplitude and the phase of the electrical digital signal are discriminated by the discriminating unit 6. Further, the degradation monitoring unit 8 detects the degree of degradation of the output of the polarization dispersion compensating unit 4, and the compensation control unit 7 provides the polarization dispersion compensating unit 4 with a compensation signal in order to compensate for the polarization dispersion based on the degree of degradation. The polarization dispersion is compensated for in this manner. Here, the compensation of the polarization dispersion is performed in the optical state, without converting the optical signal into an electrical signal.

As described above, although the conventional system shown in FIG. 1 is capable of compensating for polarization dispersion at a high speed, a problem is that the polarization dispersion compensating unit 4, the compensation control unit 7, and the degradation monitoring unit 8, which are constituted by optical components, cannot be miniaturized, and cannot be economically built.

Further, a system that performs optimal control of a discriminating point is proposed wherein the optical polarization dispersion compensation is replaced by electrically monitoring a bit error rate (Patent Reference 1).

However, “automatic equalization system” disclosed by Patent Reference 1 is for controlling an optimal discriminating point at an initial setup where the control speed is allowed to be low, taking dozens of seconds. The control speed of not only Patent Reference 1, but also other conventional discriminating point controls is low. This is because objectives of the conventional discriminating point controls, wherein rapidity is not a requirement, are different from the objective of the present invention as described below. Generally, the conventional control systems evaluate bit errors under conditions where a bit error rate is low, taking a long time.

On the other hand, the waveform distortion due to the polarization dispersion often produces a high-speed wave change. The conventional optimal control of the discriminating point by electrically monitoring the bit error rate is of a low speed, and cannot swiftly compensate for the degradation due to the polarization dispersion.

Patent Reference 1: JPA 9-326755

Non-Patent Reference 1: H. Ooi, et. al., “Automatic Polarization-Mode Dispersion Compensation in 40-Gbit/s Transmission”, IOOC '99 WE5.

### SUMMARY OF THE INVENTION

It is a general object of the present invention to provide a digital signal receiving apparatus, an optical transmission apparatus that includes the digital signal receiving apparatus, and a discriminating point control method that substantially obviate one or more of the problems caused by the limitations and disadvantages of the related art.

A specific object of the present invention is to provide a digital signal receiving apparatus, an optical transmission apparatus that includes the digital signal receiving apparatus, and a discriminating point control method that can be constituted small and made economically.

In order to attain the objectives, the digital signal receiving apparatus of the present invention includes a receiving signal discriminating unit, an error monitoring unit configured to monitor a discriminating bit error of the receiving signal discriminating unit, and a discriminating point control unit configured to control the discriminating point of the receiving signal discriminating unit. There, the discriminating point control unit monitors an output of the error monitoring unit, detects a discriminating point that provides the lowest bit error rate, and sets the detected discriminating point that provides the lowest bit error rate as the discriminating point of the receiving signal discriminating unit.

Further, in order to attain the objectives, the present invention provides the discriminating point control method of controlling the discriminating point of a main signal discriminating unit of the digital signal receiving apparatus. The digital signal receiving apparatus includes a main signal discriminating unit configured to discriminate a main signal of the received signal, a monitor signal discriminating unit configured to discriminate a monitor signal of the received signal, and a discriminating point control unit configured to control discriminating points of the main signal discriminating unit and the monitor signal discriminating unit. The discriminating point control unit monitors the output of the error monitoring unit, detects a discriminating point that provides the lowest bit error rate, and uses the detected discriminating point as the discriminating point of the receiving signal discriminating unit.

### BRIEF DESCRIPTION OF THE DRAWINGS

Features, advantages, and other purposes of the present invention will become still clearer by reading the following explanation, referring to attached drawings.

FIG. 1 is a block diagram of an example of a conventional system that automatically compensates for polarization dispersion.

FIG. 2 gives charts for explaining a control of moving a discriminating point to the optimal position corresponding to wave degradation.

FIG. 3 is a block diagram of the first embodiment of the present invention.

FIG. 4 is a flowchart of the first discriminating point control method.

FIG. 5 is a block diagram of the second embodiment of the present invention.

FIGS. 6A and 6B give charts for explaining expansion of a discriminating point.

FIG. 7 is a flowchart of the second discriminating point control method.

FIG. 8 is a block diagram of the third embodiment of the present invention.

FIGS. 9A and 9B give charts for explaining control of the discriminating point by a discriminating point control unit.

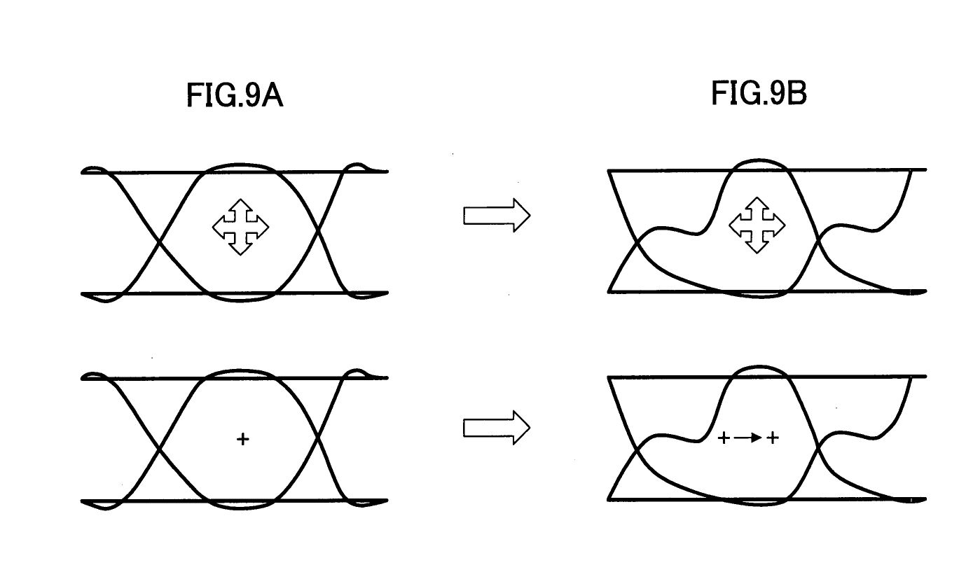

### DESCRIPTION OF THE PREFERRED EMBODIMENTS

In the following, embodiments of the present invention are described with reference to the accompanying drawings.

Polarization dispersion causes waveform distortion of an optical pulse. If the waveform is distorted, the distance between a discriminating point and a signal waveform becomes small, and a bit error arises. According to the present invention, the bit error is monitored, and according to waveform distortion, discrimination level and timing are shifted so that the bit error is minimized. For example, in the case that the waveform distortion is such that a high-level side falls, the discriminating point is lowered; and conversely, when the waveform distortion is such that a low-level side rises, the discriminating point is raised.

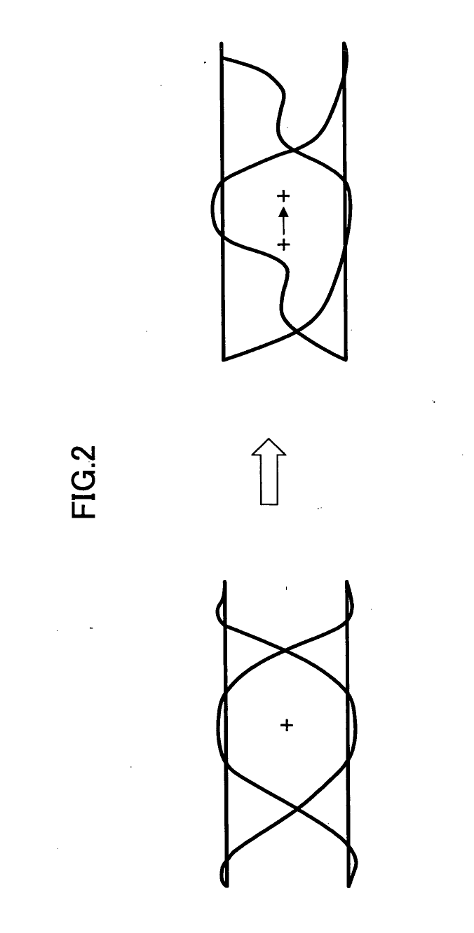

Further, if the waveform distortion is such that the eye pattern opens in the second half of the pulse as shown in FIG. 2, the discriminating point is delayed.

The waveform distortion by polarization dispersion tends to cause a comparatively high-speed waveform change. For example, during maintenance work, if an optical fiber in use is touched by hand, since the relation between the main axis of the polarization of the optical fiber and the polarization of the signal light changes, correspondingly the waveform distortion changes at a high speed. In the present invention, the discriminating point is controlled at a high speed of at least 100 ms in order to respond to a quick waveform distortion. Nevertheless, when the waveform distortion changes greater still, the discriminating point control can be carried out at a 10 ms speed, or even faster.

When the control is performed based on a bit error, high-speed control is attained by monitoring and controlling while the bit error rate is high. For this reason, according to the present invention, the discriminating point of the discriminating unit is controlled where the bit error rate is high. Further, an error correction unit is provided following the discriminating unit if needed.

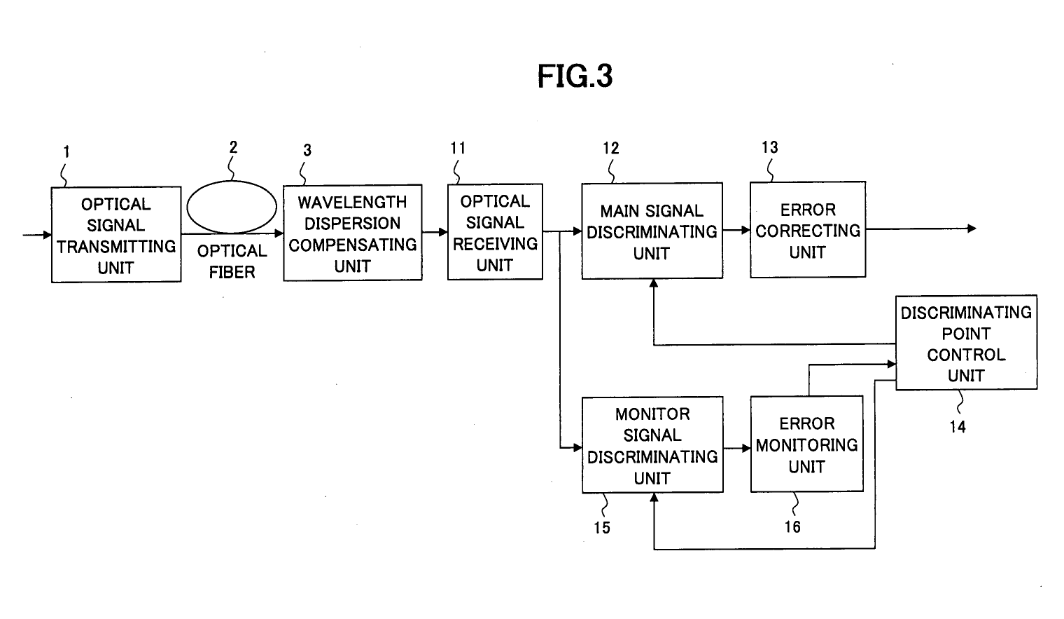

FIG. 3 is a block diagram of the first embodiment of the present invention. The system shown in FIG. 3 includes an optical signal transmitting unit 1, an optical fiber 2, a wavelength dispersion compensating unit 3, an optical signal receiving unit 11, a main signal discriminating unit 12, an error correction unit 13, a discriminating point control unit 14, a monitor signal discriminating unit 15, and a error monitoring unit 16.

Here, the optical signal receiving unit 11, the main signal discriminating unit 12, the error correction unit 13, the discriminating point control unit 14, the monitor signal discriminating unit 15, and the error monitoring unit 16 constitute a digital signal receiving apparatus.

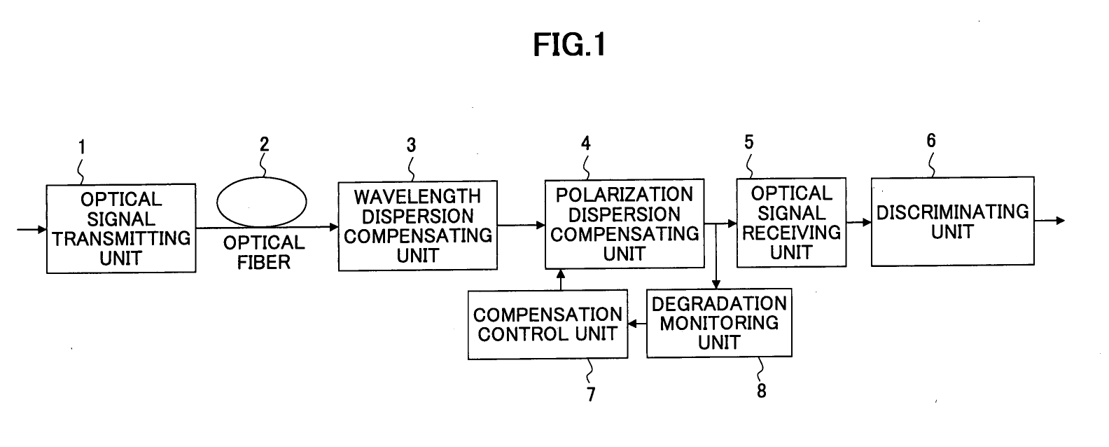

The main signal discriminating unit 12, the error correction unit 13, the discriminating point control unit 14, the monitor signal discriminating unit 15, and the error monitoring unit 16 are units that handle electrical signals, replacing the polarization dispersion compensating unit 4, the compensation control unit 7, and the degradation monitoring unit 8 in FIG. 1.

The optical signal transmitting unit 1 outputs an optical digital signal to the optical fiber 2. The optical digital signal is subjected to wavelength dispersion and polarization dispersion by the optical fiber 2. Then, on the digital signal receiving apparatus side, the main signal discriminating unit 12 is provided, which is capable of automatically and adaptively setting up a discriminating point at a high speed. In this manner, on the digital signal receiving apparatus side, after wavelength dispersion is compensated for by the wavelength dispersion compensating unit 3, bit errors due to the waveform distortion of polarization dispersion are removed by the main signal discriminating unit 12 and the error correction unit 13.

The main signal discriminating unit 12 discriminates a main signal of the digital signal that is converted into an electrical signal by the optical signal receiving unit 11. Here, two values of the signal received at predetermined timing are discriminated at an optimal discriminating point that the discriminating point control unit 14 sets up.

The error correction unit 13 corrects a bit error of the signal discriminated by the main signal discriminating unit 12. The error correction unit 13 is capable of correcting, e.g., a bit error rate of 10⁻⁴ to 10⁻¹².

The monitor signal discriminating unit 15 discriminates the monitor signal of the digital signal that is converted into the electrical signal by the optical signal receiving unit 11. Here, two values of the signal are discriminated at the discriminating point that the discriminating point control unit 14 sets up.

The error monitoring unit 16 monitors a bit error of the signal discriminated by the monitor signal discriminating unit 15. Monitoring results are provided to the discriminating point control unit 14.

The discriminating point control unit 14 moves the discriminating point of the monitor signal discriminating unit 15 in the directions of the amplitude and the directions of the phase, and a discriminating bit error occurs as described in detail below. Further, the main signal discriminating unit 14 detects the center of discriminating points at which a bit error is generated based on the output of the error monitoring unit 16, and sets up the center (where the bit error is minimum) of the discriminating points as the discriminating point of the main signal discriminating unit 12.

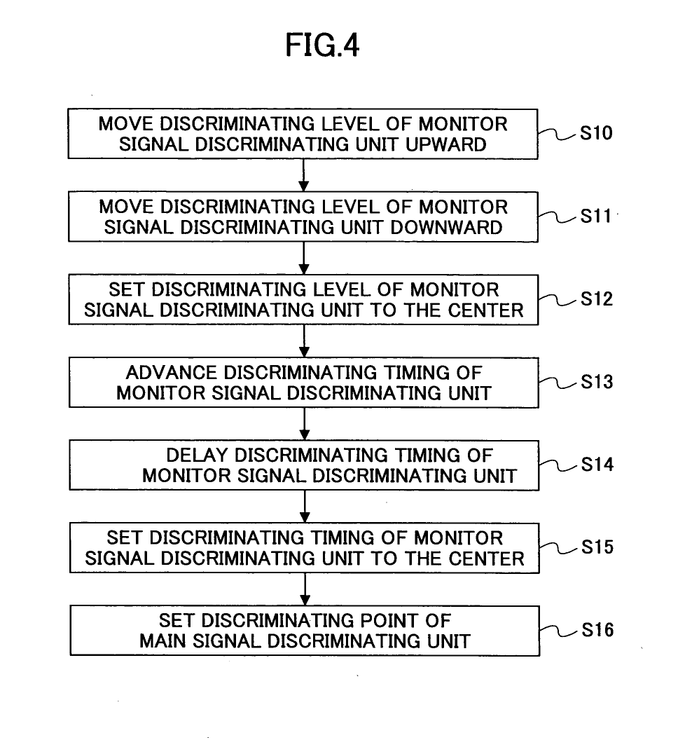

Specifically, the high-speed discriminating point control method using the bit error is carried out as follows (refer to FIG. 4).

(1) The discriminating point control unit 14 moves the discrimination point (level) of the monitor signal discriminating unit 15 upwards until the bit error rate reaches a predetermined rate (Step S10).

(2) Next, the discriminating point control unit 14 moves the discrimination level of the monitor signal discriminating unit 15 downward until the bit error rate reaches the predetermined rate (Step S11).

(3) Next, the discriminating point control unit 14 sets up the discrimination level at the center of the discrimination level of (1) above, and the discrimination level of (2) above (Step S12).

(4) Next, the discriminating point control unit 14 advances discriminating point (timing) of the monitor signal discriminating unit 15 until the bit error rate reaches a predetermined rate (Step S13).

(5) Next, the discriminating point control unit 14 delays the discriminating timing of the monitor signal discriminating unit 15 until the bit error rate reaches the predetermined rate (Step S14).

(6) Next, the discriminating point control unit 14 sets up the discriminating timing at the center of the discriminating timing of (4) above, and the discriminating timing of (5) above. The discriminating point having the discrimination level of (3) and the discriminating timing of (5) serves as the optimal discriminating point (Step S15).

(7) Next, the discriminating point control unit 14 sets the discriminating point of the main signal discriminating unit 12 at the optimal discriminating point of (6) above (Step S16). In this manner, the optimal discriminating point of the main signal discriminating unit 12 is set up.

Here, if each step is performed in 10 ms, the discriminating point of the optimal main signal discriminating unit 12 can be set up through all the seven steps in 70 ms. For example, a bit error is counted at Step 10, moving the discrimination level at intervals of 1 ms. An amount of incrementing/decrementing the amplitude and the phase (step size) is set up such that the predetermined rate of a bit error may be obtained within 10 steps. Here, the discriminating point is moved until ten bit errors occur in a 1 ms period. For example, for a transmission at a bit rate of 40 Gb/s, ten bit errors in 1 ms represent a bit error rate of 2.5×10⁻⁷. If the quality of service required of a system is a bit error rate of 10⁻¹² or less, the bit error rate of 2.5×10⁻⁷ is corrected to the bit error rate 10⁻¹² by the error correction unit 13. Step 11, Step 13, and Step 14 can be performed in 10 ms as described with reference to Step 10. Further, since Step 12, Step 15, and Step 16 are simply to setup a voltage and timing, these steps can be performed in 10 ms or less.

Therefore, the optimal discriminating point of the main signal discriminating unit can be set up in 70 ms without affecting the quality of service.

Here, the control of the discriminating point by the discriminating point control unit 14 is performed at any time as required. For example, the 70 ms process can be repeatedly performed.

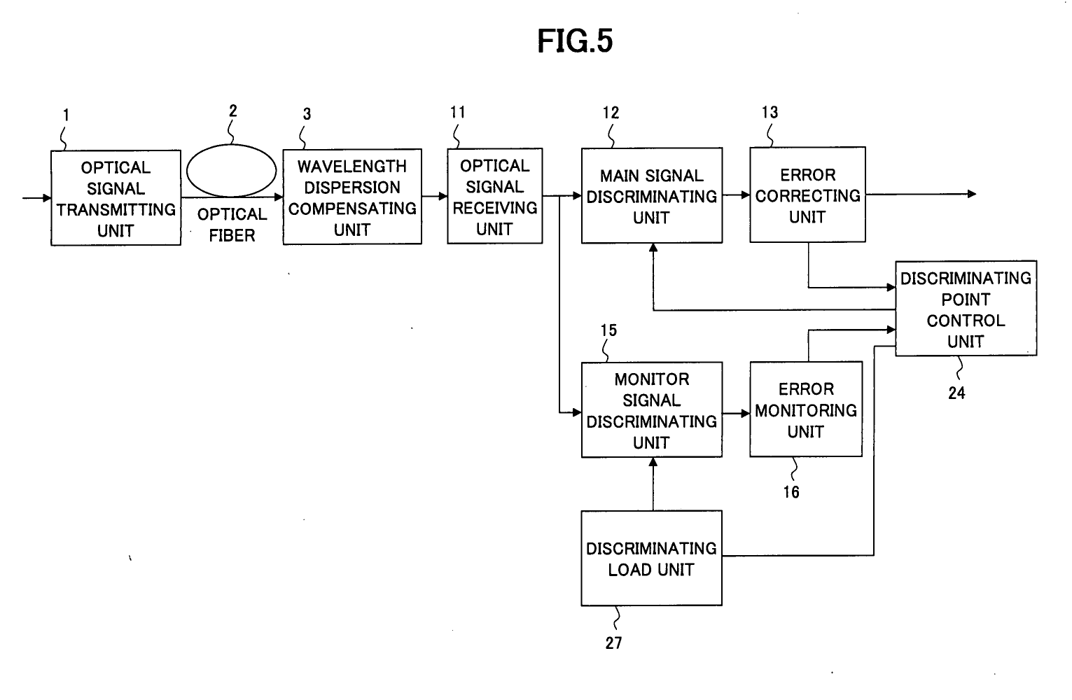

FIG. 5 is a block diagram of the second embodiment of the present invention. The system in FIG. 5 includes the optical signal transmitting unit 1, the optical fiber 2, the wavelength dispersion compensating unit 3, the optical signal receiving unit 11, the main signal discriminating unit 12, the error correction unit 13, a discriminating point control unit 24, the monitor signal discriminating unit 15, a error monitoring unit 16, and a discriminating point load unit 27.

Here, the optical signal receiving unit 11, the main signal discriminating unit 12, the error correction unit 13, the discriminating point control unit 24, the monitor signal discriminating unit 15, the error monitoring unit 16, and the discriminating point load unit 27 constitute a digital signal receiving apparatus.

The main signal discriminating unit 12, the error correction unit 13, the discriminating point control unit 24, the monitor signal discriminating unit 15, the error monitoring unit 16, and the discriminating point load unit 27 are units that handle electrical signals, replacing the polarization dispersion compensating unit 4, the compensation control unit 7, and the degradation monitoring unit 8 in FIG. 1.

FIG. 5 differs from FIG. 3 in that the discriminating point load unit 27 is added. Here, the optical signal transmitting unit 1, the optical fiber 2, the wavelength dispersion compensating unit 3, the optical signal receiving unit 11, the main signal discriminating unit 12, the error correction unit 13, the monitor signal discriminating unit 15, and the error monitoring unit 16 in FIG. 5 can be the same as the optical signal transmitting unit 1, the optical fiber 2, the wavelength dispersion compensating unit 3, the optical signal receiving unit 11, the main signal discriminating unit 12, the error correction unit 13, the monitor signal discriminating unit 15, respectively, of FIG. 3.

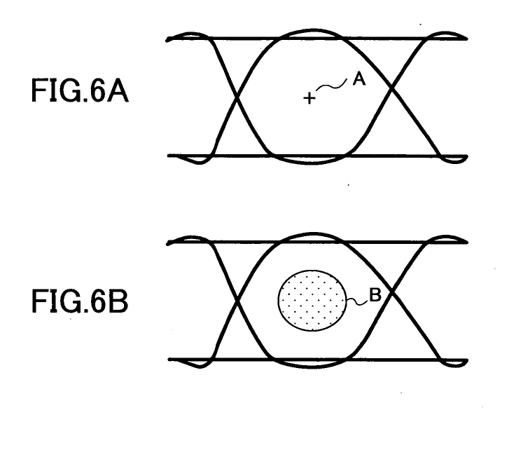

The discriminating point load unit 27 of FIG. 5 expands the discriminating point. For example, when a discriminating point A is provided by the discriminating point control unit 26, as shown in FIG. 6A, the discriminating point load unit 27 expands the discriminating point A to a circle B (hereafter the discriminating point expanded by the discriminating point control unit is called “the expanded discriminating point”), for example, as shown in FIG. 6B. Expansion of the discriminating point A is carried out at a high speed in the four directions, and slant directions such that bit errors are easily generated. In addition, the expansion does not have to be in the shape of the circle.

The discriminating point control unit 26 monitors the output of the error monitoring unit 16, and continuously controls the expanded discriminating point such that the discriminating bit error is minimized. The discriminating point of the main signal discriminating unit 12 is always interlocked with the center of the expanded discriminating point.

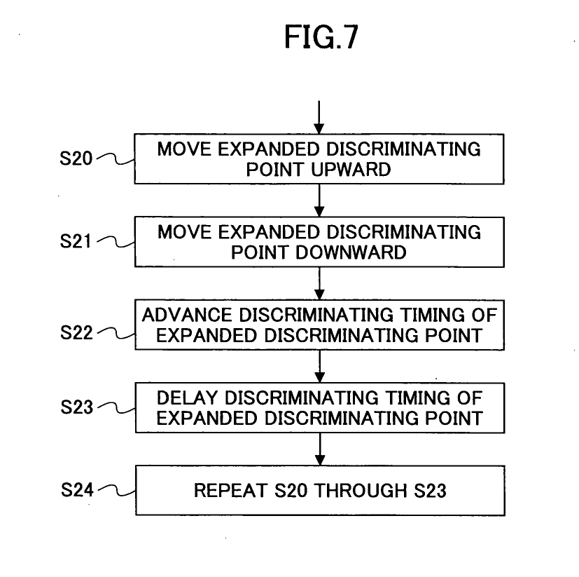

Specifically, the high-speed discriminating point control method using the expanded discriminating point is carried out as follows (refer to FIG. 7).

(1) The expanded discriminating point is moved upwards (Step S20).

(2) If a bit error rate increases, the expanded discriminating point is moved downward (Step S21).

(3) Discriminating timing of the expanded discriminating point is advanced (Step S22).

(4) If the bit error increases, the discriminating timing is delayed (Step S23).

(5) The above (1) through (4), i.e., Steps S20 through 23 are continuously repeated (Step S24).

(6) In addition, the discriminating point of the main signal discriminating unit 12 is moved always while Steps S20 through 23 are continuously repeated, interlocking with the center of the expanded discriminating point.

As described above, the monitor signal discriminating unit 15 discriminates using the expanded discriminating point, which generates a higher bit error rate. Since the generated bit error rate is high, the discriminating point is controlled to the optimal value (point of the bit error minimum) at a high speed. Since the discriminating point of the main signal discriminating unit 12 is moved always interlocking with the center of the expanded discriminating point, the optimal position is obtained at a high speed.

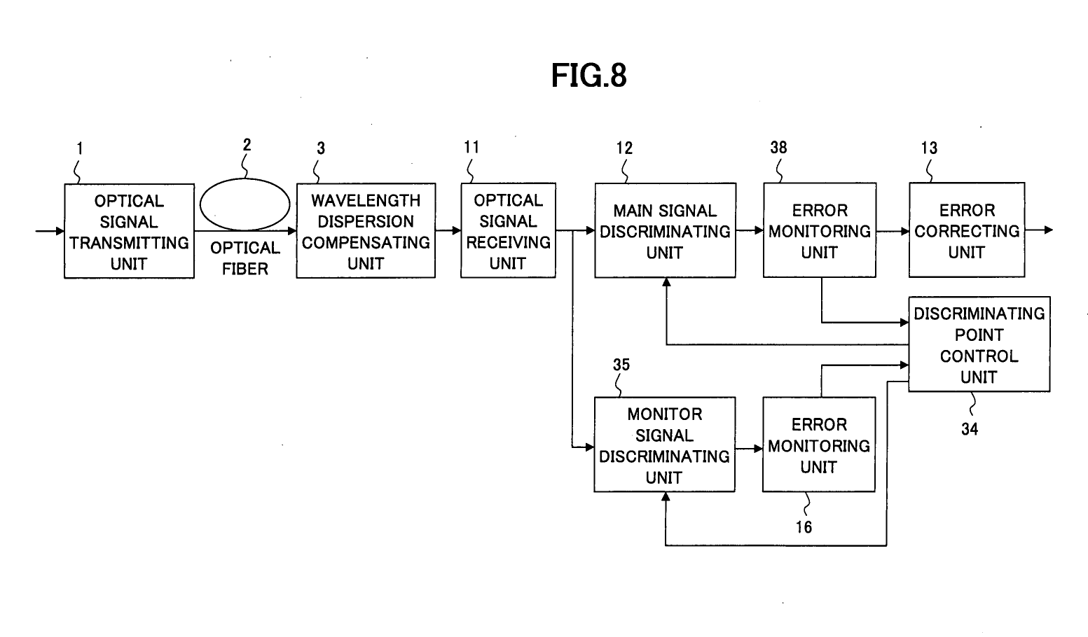

FIG. 8 is a block diagram of the third embodiment of the present invention. The system shown in FIG. 5 includes the optical signal transmitting unit 1, the optical fiber 2, the wavelength dispersion compensating unit 3, the optical signal receiving unit 11, the main signal discriminating unit 12, the error correction unit 13, the error monitoring unit 16, a discriminating point control unit 34, a monitor signal discriminating unit 35, and a error monitoring unit 38.

Here, the optical signal receiving unit 11, the main signal discriminating unit 12, the error correction unit 13, the error monitoring unit 16, the discriminating point control unit 34, the monitor signal discriminating unit 35, and the error monitoring unit 38 constitute a digital signal receiving apparatus.

The main signal discriminating unit 12, the error correction unit 13, the error monitoring unit 16, the discriminating point control unit 34, the monitor signal discriminating unit 35, and the error monitoring unit 38 are units that handle electrical signals, replacing the polarization dispersion compensating unit 4, the compensation control unit 7, and the degradation monitoring unit 8 of FIG. 1.

FIG. 8 differs from FIG. 3 in that the former includes the error monitoring unit 38. Here, the optical signal transmitting unit 1, the optical fiber 2, the wavelength dispersion compensating unit 3, the optical signal receiving unit 11, the main signal discriminating unit 12, the error correction unit 13, and the error monitoring unit 16 in FIG. 8 can be the same as the optical signal transmitting unit 1, the optical fiber 2, the wavelength dispersion compensating unit 3, the optical signal receiving unit 11, the main signal discriminating unit 12, the error correction unit 13, and the error monitoring unit 16, respectively, in FIG. 3.

The error monitoring unit 38 of FIG. 8 monitors the bit error rate of the signal discriminated by the main signal discriminating unit 12. Monitoring results are provided to the discriminating point control unit 34.

The discriminating point control performed by the structure shown in FIG. 8 is as follows.

(1) The discriminating point control unit 34 controls the discriminating point of the monitor signal discriminating unit 35 such that a discriminating point that provides the lowest the bit error rate of the monitor signal discriminating unit 35 is set up.

(2) The bit error rate detected by the error monitoring unit 38 is compared with the bit error rate detected by the error monitoring unit 16. When the bit error rate detected by the error monitoring unit 38 is lower than the bit error rate detected by the error monitoring unit 16, the discriminating point of the main signal discriminating unit 12 is not moved.

(3) On the other hand, when the bit error rate detected by the error monitoring unit 38 is higher than the bit error rate detected by the error monitoring unit 16, the discriminating point of the main signal discriminating unit 12 is moved to the discriminating point of the monitor signal discriminating unit 35. In this manner, high-speed control can be performed.

Here, in the case of setting up the discriminating point of the monitor signal discriminating unit 35 such that the bit error rate is minimized by controlling the discriminating point of the monitor signal discriminating unit 35, the following methods can be used.
(i) The discriminating point is moved in the directions of the amplitude and the directions of the phase, and a discriminating point that provides the lowest discriminating bit error is detected.
(ii) The discriminating point is moved in the directions of the amplitude and the directions of the phase, and the center of discriminating points that generate a bit error is detected.
(iii) The discriminating point is expanded, and the center of the expanded discriminating point that provides the lowest bit error rate is detected.
(iv) The discriminating point is moved at random, and the center of discriminating points that generate a bit error is detected.

Further, control of the discriminating point by the discriminating point control unit 34 can be performed any time. For example, the control can be repeatedly performed, or alternatively, the control can be performed when the discriminating bit error rate of the main signal discriminating unit 12 becomes higher than a predetermined value.

An optical transmission apparatus that includes the digital signal receiving apparatus such as shown in FIG. 3, FIG. 5, and FIG. 8 can also be constituted.

Further, although the embodiments are described as using a two-value digital signal, the present invention is also applicable to a multiple-value signal and a QAM (Quadrature Amplitude Modulation) signal.

Further, the present invention is not limited to these embodiments, but various variations and modifications may be made without departing from the scope of the present invention.

1. A digital signal receiving apparatus, comprising:
a receiving signal discriminating unit;
an error monitoring unit configured to monitor a discriminating error of the receiving signal discriminating unit; and
a discriminating point control unit configured to control a discriminating point of the receiving signal discriminating unit, wherein
the discriminating point control unit
monitors an output of the error monitoring unit,
moves the discriminating point of the receiving signal discriminating unit in the amplitude directions and the phase directions such that an error occurs,
detects a central point of discriminating points that generate bit errors, and
sets the central point of the discriminating points as the discriminating point of the receiving signal discriminating unit.

2. A digital signal receiving apparatus, comprising:
a main signal discriminating unit configured to discriminate a main signal of a received signal;
a monitor signal discriminating unit configured to discriminate a monitor signal of the received signal;
an error monitoring unit configured to monitor a discriminating error of the monitor signal discriminating unit; and
a discriminating point control unit configured to control discriminating points of the main signal discriminating unit and the monitor signal discriminating unit, wherein the discriminating point control unit
monitors an output of the error monitoring unit,
moves the discriminating point of the monitor signal discriminating unit in the amplitude directions and the phase directions such that a discriminating error occurs,
detects a central point of discriminating points that generate errors, and
sets the central point as the discriminating point of the main signal discriminating unit.

3. A digital signal receiving apparatus, comprising:
a main signal discriminating unit configured to discriminate a main signal of a received signal;
a monitor signal discriminating unit configured to discriminate a monitor signal of the received signal;
an error monitoring unit configured to monitor a discriminating error of the monitor signal discriminating unit; and
a discriminating point control unit configured to control discriminating points of the main signal discriminating unit and the monitor signal discriminating unit, wherein the discriminating point control unit
expands the discriminating point of the monitor signal discriminating unit,
monitors an output of the error monitoring unit,
moves the expanded discriminating point in the amplitude directions and the phase directions,
controls the discriminating point such that a bit error rate is minimized (the discriminating point being the center of the expanded discriminating point that provides the lowest discriminating bit error rate, and called “the discriminating point of the minimum bit error rate of the expanded discriminating point”), and
sets the discriminating point of the minimum bit error rate of the expanded discriminating point as the discriminating point of the main signal discriminating unit.

4. A digital signal receiving apparatus, comprising:
a main signal discriminating unit configured to discriminate a main signal of a received signal;
a monitor signal discriminating unit configured to discriminate a monitor signal of the received signal;
an error monitoring unit configured to monitor a discriminating error of the main signal discriminating unit and the monitor signal discriminating unit; and
a discriminating point control unit configured to control discriminating points of the main signal discriminating unit and the monitor signal discriminating unit,
wherein the discriminating point control unit, based on an output of the error monitoring unit,
moves the discriminating point in the amplitude directions and the phase directions,
detects the discriminating point that provides the lowest discriminating bit error rate,
compares the lowest discriminating bit error rate with the discriminating bit error rate of the main signal discriminating unit, and
sets the discriminating point that provides the lowest discriminating bit error rate as the discriminating point of the main signal discriminating unit if the discriminating bit error rate of the main signal discriminating unit exceeds the lowest discriminating bit error rate.

5. A digital signal receiving apparatus, comprising:
a main signal discriminating unit configured to discriminate a main signal of a received signal;
a monitor signal discriminating unit configured to discriminate a monitor signal of the received signal;
an error monitoring unit configured to monitor a discriminating error of the main signal discriminating unit and the monitor signal discriminating unit; and
a discriminating point control unit configured to control discriminating points of the main signal discriminating unit and the monitor signal discriminating unit,
wherein the discriminating point control unit, based on an output of the error monitoring unit,
moves the discriminating point of the monitor signal discriminating unit in the amplitude direction and the phase direction such that a discriminating error occurs,
detects the center of discriminating points that generate a discriminating bit error,
compares a discriminating bit error rate of the center with the discriminating bit error rate of the output of the main signal discriminating unit, and
sets “the discriminating point of the minimum bit error of the discriminating point” as the detected center of the discriminating points if the discriminating bit error rate of the output of the main signal discriminating unit exceeds the discriminating bit error rate of the detected center of the discriminating point.

6. The digital signal receiving apparatus as claimed in claim 1, wherein the discriminating point control unit repeatedly controls the discriminating point.

7. The digital signal receiving apparatus as claimed in claim 2, wherein the discriminating point control unit controls the discriminating point of the main signal discriminating unit and/or the monitor signal discriminating unit if the discriminating bit error rate of the main signal discriminating unit is greater than a predetermined value.

8. An optical transmission apparatus that receives an optical signal, comprising:
the digital signal receiving apparatus as claimed in claim 1.

9. A discriminating point control method of controlling a discriminating point of a receiving signal discriminating unit of a digital signal receiving apparatus that has a discriminating point control unit configured to control the discriminating point of the receiving signal discriminating unit, comprising:
a step of controlling the discriminating point so that a discriminating error is generated, the step being performed by the receiving signal discriminating unit;
a step of detecting a center of discriminating points where errors are generated; and
a step of setting the detected center as the discriminating point of the receiving signal discriminating unit.

10. A discriminating point control method of controlling a discriminating point of a main signal discriminating unit of a digital signal receiving apparatus that has the main signal discriminating unit configured to discriminate a main signal of a received signal, a monitor signal discriminating unit configured to discriminate a monitor signal of the received signal, and a discriminating point control unit configured to control the discriminating points of the main signal discriminating unit and the monitor signal discriminating unit, comprising:
a step of monitoring an output of an error monitoring unit, the step being performed by the discriminating point control unit;
a step of moving the discriminating point of the monitor signal discriminating unit in the amplitude directions and the phase directions such that a discriminating error occurs;
a step of detecting a center of discriminating points where errors are generated; and
a step of setting the detected center of the discriminating points as the discriminating point of the main signal discriminating unit.

11. A discriminating point control method of controlling a discriminating point of a main signal discriminating unit of a digital signal receiving apparatus that has the main signal discriminating unit configured to discriminate a main signal of a received signal, a monitor signal discriminating unit configured to discriminate a monitor signal of the received signal, and a discriminating point control unit configured to control the discriminating points of the main signal discriminating unit and the monitor signal discriminating unit, comprising:
a step of expanding the discriminating point of the monitor signal discriminating unit, the step being performed by the discriminating point control unit;
a step of monitoring an output of an error monitoring unit;
a step of moving the expanded discriminating point in the amplitude directions and the phase directions such that the expanded discriminating point provides the minimum discriminating bit error rate; and
setting the center of the expanded discriminating point providing the minimum discriminating bit error rate as the discriminating point of the receiving signal discriminating unit.
